(19) United States
(12) Patent Application Publication
(10) Pub. No.: US 2008/0126893 A1
(43) Pub. Date: May 29, 2008

(54) METHOD OF REFRESHING A DYNAMIC RANDOM ACCESS MEMORY AND CORRESPONDING DYNAMIC RANDOM ACCESS MEMORY DEVICE, IN PARTICULAR INCORPORATED INTO A CELLULAR MOBILE TELEPHONE

(75) Inventor: Michel Harrand, Saint-Egreve (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 11/772,385

(22) Filed: Jul. 2, 2007

(30) Foreign Application Priority Data
Jul. 3, 2006 (FR) 0605988

(51) Int. Cl. G11C 29/52; G06F 11/263

(52) U.S. Cl. 714/719; 365/222; 714/E11.177

(57) ABSTRACT

A method is for refreshing a dynamic random access memory coupled to an error correction system, which uses an error correcting code. The dynamic random access memory includes groups of memory cells storing bits, each group of memory cells being subdivided into packets of memory cells. Each packet of memory cells is supplemented with the error correcting code. The method includes performing a retention test on each group of memory cells, and increasing a memory refresh frequency if a number of test groups of memory cells having at least one erroneous packet is greater than a threshold.

### FIELD OF THE INVENTION

The invention relates to dynamic random access memories, that is to say, those using periodic refreshing of the data stored in the memory cells of these memories, and more particularly, to the refreshing of these dynamic random access memories.

### BACKGROUND OF THE INVENTION

Third-generation cellular mobile telephones may use the integration of large quantities of memory; however, the cost of the product may yet remain low. The use of dynamic random access memories, in place of the static random access memories, allows this rise in memory capacity while maintaining a low cost.

However, an important constraint in this type of application may be the need to provide a low level of power consumption while the telephone is on standby, so as not to discharge the batteries too quickly. However, although dynamic random access memories have a smaller static leakage current than static random access memories, they need to be refreshed continuously if the data is to be preserved in standby mode. This refreshing consumes energy and it is important to minimize this energy consumption. The refresh frequency is given by the number of memory pages to be refreshed and by the retention time of the memory. This retention time is essentially related to the junction leakages in the transistors of the memory cells.

French Patent Application No. 0301005, which is in the name of the Assignee of the present application, discloses a method of refreshing random access memories, which uses the measurement of the actual retention time of all the memory cells of the memory to adjust the latter's refresh period. More precisely, for a group of selected memory cells, the number of accumulated errors is observed when the refresh frequency of these memory cells is decreased. The number of errors counted is compared with a predetermined threshold, and according to the result of this comparison, the refresh period is increased or reduced.

However, in addition to the errors related to the junction leaks in the transistors of the memory cells, some errors are due to hardware defects in the memory cell, and to the wear and tear of the components in the memory, for example. Conventionally, to prevent this type of error, the memory circuit undergoes a prior so-called “burn-in” operation before it is brought into service. This operation comprises imposing unfavorable operating constraints on the memory cells of the memory, so as to eliminate memory circuits that are liable not to operate in the short term.

In the absence of a prior burn-in operation, errors due to defective memory cells, for example, ones having an extremely low retention time, could appear during the use of the memory on a certain number of items, thus degrading the product quality level. However, though the burn-in operation is beneficial for eliminating circuits comprising the aforesaid defective memory cells, burn-in may be particularly expensive.

Another drawback may reside in a generally performed test of the memory cell. This test comprises in imposing the value “1” (corresponding to a maximum voltage across the terminals of the capacitor of the memory cell) on all the bits of the tested packets of memory cells (after having separately saved the actual value of these bits). Then, after a latency period, the bits that have switched to “0” are counted (see French Patent Application No. 0301005, also in the name of the Assignee of the present application), these bits switching on account of a leak in the junction of the transistor of a weaker memory cell.

Now, the weak memory cells storing the value “0” do not pose any storage problem. Consequently, by imposing the value “1” on all the bits, all the weak memory cells are detected, even those whose defect is of no importance, given that they have to save the “0” bits. Consequently, the refresh frequency is increased for memory cells whose leaks have no influence on the data stored.

### SUMMARY OF THE INVENTION

An object of the invention is to provide a dynamic random access memory refresh device which has not been made to undergo any burn-in operation, but the refresh period may be adjusted, such as in an optimal manner, so as to limit the power consumption of the device.

Another object is to further reduce the power consumption brought about by the refreshing of the memory, in particular, by improving the test performed at the memory cell level. As the mechanism for measuring the retention may be somewhat slow (this not posing a problem if the temperature increases slowly), another object is to reduce problems appearing if the temperature rises more quickly than the system measuring the retention, given that temperature influences the retention time of the memory cells.

According to a first aspect, there is provided a method of refreshing a dynamic random access memory coupled to an error correction system which uses an error correcting code (ECC). The memory comprises groups of memory cells able to store bits, each group of memory cells being subdivided into packets of memory cells. According to a general characteristic of this aspect, each packet of memory cells is supplemented with a few bits forming the error correcting code, and a retention test is performed on each group of memory cells. The group under test is saved in a safe memory area (that is to say a memory designed to avoid errors related to junction leaks, such as, a static memory or a dynamic random access memory refreshed at high frequency; the user has no access to this safe memory area) after correction of errors therein by the error correction system, so as to obtain a model group comprising model packets.

After a latency period, a bitwise comparison is performed between the model group and the group that has not been corrected or refreshed during the latency period. The erroneous bits having values differing from those of the bits of the corresponding model packet are detected in each packet of the group, and the packet is considered to be erroneous if it comprises a larger number of erroneous bits than a limit value less than or equal to the number of bits capable of being corrected by the error correction system. The value of the memory refresh frequency is increased if the number of groups of memory cells comprising at least one erroneous packet is greater than a fixed threshold.

Stated otherwise, a model group is devised for each group of cells (for example, for each memory page of the memory), and this model group is compared with the content uncorrected and unrefreshed for a certain duration, of the same group of memory cells. If on completion of the comparison of the two groups (model and nonrefreshed), the number of errors observed for one of the packets of the group (for example, for a word) is greater than the number of errors that the error correcting code is capable of correcting (more generally greater than a limit value less than or equal to this number of errors), then the word in question is considered to be erroneous.

If one or more groups of memory cells comprise at least one erroneous word, then the refresh frequency of the memory is increased. If when all the pages have been tested, no page contains a word exhibiting more than one error (more than k errors in the general case, with k≦N, N being a number of errors that can be corrected by the error correction system, as a function of the error correcting code used), then the reference frequency of the memory is decreased.

Indeed, the use of an error correction system makes it possible to ignore a certain number of errors (according to the number of errors that the error correction system in question is capable of correcting), since each time the erroneous data item is transferred out of the memory, the system may automatically correct these errors.

In this way, an error may not be systematically counted if a memory cell, even one having junction leaks, has to store the “0” bit. The error correction system may be capable of correcting one bit per packet of memory cells. In this case, the error correcting code may have the advantage of being particularly simple to implement. The latency period can comprise N refresh periods, N being an integer.

According to an embodiment, on completion of the detection of the erroneous bits, the content of the group of model memory cells is supplemented with an error correcting code and then it is saved within the dynamic random access memory, in place of the corresponding group of memory cells. According to another embodiment, as long as the number of groups of memory cells comprising at least one erroneous packet, termed groups of weak memory cells, is less than or equal to the fixed threshold (that is to say k such that k≦N, N being the number of errors that can be corrected by the error correction system as a function of the error correction code which has previously been used), then the address of the group of weak memory cells may be stored so as to refresh them at the maximum frequency.

According to another embodiment, the increase is performed if the refresh frequency has not reached its maximum value. When all the groups of memory cells of the memory have been tested, the value of the refresh frequency may be decreased if it has not been increased in the course of the test. When all the groups of memory cells of the memory have been tested, if the number of groups of memory cells comprising at least one erroneous packet, termed a group of weak memory cells, is greater than or equal to the fixed threshold and if the refresh frequency is at its maximum value, then the number of groups of weak memory cells may be considered to be zero.

According to another embodiment, each group of memory cells forming a group of test cells may be selected successively so as to perform the retention test. In parallel with the retention test, the whole set of memory cells of the memory may be refreshed cyclically, with the exception of the group of test cells. For example, the memory can be organized pagewise, each group of memory cells can correspond to an integer number of pages, and each packet of memory cells corresponds to a word of a page.

It is possible to impose an increase in the refresh frequency if the variation in the temperature within the memory exceeds a chosen threshold. For example, the memory can be incorporated into an apparatus possessing a standby mode and an active operating mode, and the retention test is performed on all the memory cells at least in the course of the standby mode. The apparatus can be a component of a wireless communication system, for example, a cellular mobile telephone.

According to another aspect, there is provided a device for refreshing a dynamic random access memory comprising groups of memory cells able to store bits, each group of memory cells being subdivided into packets of memory cells. According to a general characteristic, the dynamic random access memory is coupled to an error correction system. In view of which, an error correcting code is able to correct a given number of possible erroneous bits per packet of memory cells being associated with each packet of memory cells. The device comprises test means or a retention testing module able to perform a retention test on each group of memory cells.

The device also comprises a group of memory cells comprising a safe memory area able to save the group under test after a correction of errors therein by the error correction system, so as to obtain a model group comprising model packets. The device also comprises comparison means or a comparer (MCOMP) able to perform, after a latency period, a bitwise comparison between the model group and the group that has not been corrected or refreshed during the latency period. The comparer is able to detect, in each packet of the group, the so-called erroneous bits that have different values from those of the bits of the corresponding model packet. The comparer is able to consider the packet to be erroneous if it comprises a greater number of erroneous bits than a limit value less than or equal to the number of bits that can be corrected by virtue of the error correcting code, by the error correction system.

The device comprises increase means or a refresh controller able to increase the value of the memory refresh frequency, if the number of groups of memory cells comprising at least one erroneous packet is greater than a fixed threshold. According to an embodiment, the safe memory area comprises a reserved area of the random access memory, refreshed at the maximum value of the refresh frequency, so as to save the model group. According to another embodiment, the safe memory area comprises an ancillary static memory coupled to the dynamic random access memory, so as to save the model group.

The device can further comprise supplementing means or a supplementing device coupled to the dynamic random access memory that is able to supplement the content of the group of model memory cells with an error correcting code. The supplementing means is also and able to save the coded content of the model group within the dynamic random access memory, in place of the corresponding group of memory cells.

For example, the device can further comprise a memory for weak pages, whose size is equal to the threshold and that is able to save the addresses of the groups of memory cells comprising at least one erroneous packet, termed a group of weak memory cells. The groups of weak memory cells may be advantageously refreshed at the maximum refresh value.

The device can further comprise comparison means or a comparer being able to compare the fill of the weak pages memory and the threshold. The device can further comprise recording means or a recorder being able to record the effecting of an increase in the frequency. The device can further comprise reduction means or a second refresh controller coupled to the recording means, and able to reduce the refresh frequency.

The device can further comprise drive means or a driver for the weak pages memory, which are able to update and reinitialize the weak pages memory. The retention test means or a retention testing module can further comprise selection means or a selector for successively selecting the various groups of memory cells, so as to scan the whole set of memory cells. The selected groups of memory cells form groups of test cells.

The device can further comprise refresh means or a refreshing module able to cyclically refresh the whole set of memory cells of the memory. The device can further comprise auxiliary comparison means or an auxiliary comparer coupled between the refresh means and the test means and being able to compare the addresses of the group of memory cells refreshed by the refresh means and the group of test cells, so that the refresh means do not refresh the group of test cells.

The error correction system may be able to correct one error per memory cell packet. If in this case, each packet of memory cells comprises n bits, and the comparison means may comprise, for each packet of a group of memory cells, n “EXCLUSIVE OR” logic gates, each gate being able to receive one of the bits of the model packet and the corresponding bit of the packet that has not been corrected or refreshed during the latency period, n “AND” logic gates with n−1 inverting inputs, and an “AND” logic gate with n inverting inputs, the set of “AND” logic gates being connected in parallel, to the output of the n “EXCLUSIVE OR” logic gates, and an “OR” logic gate connected to the output of the set of “AND” logic gates, able to determine whether there exist at least two bits differing between the model packet and the corresponding bit of the packet that has not been corrected or refreshed during the latency period.

According to another embodiment, if each packet of memory cells comprises n bits, the comparison means can comprise n “EXCLUSIVE OR” logic gates, each gate being able to receive one of the bits of the model packet and the corresponding bit of the packet that has not been corrected or refreshed during the latency period. There may be n−1 half-adders (ADi) connected in series and at the output of the “EXCLUSIVE OR” logic gates, able to receive, for the first half-adder, the output signals of the first two “EXCLUSIVE OR” gates, and for the others. On the one hand, a sum is delivered by the half-adder connected upstream, and on the other hand an output signal from an “EXCLUSIVE OR” logic gate is delivered, each half-adder being able to deliver a carry signal. The comparison means further comprise means for adding or an adder for adding the whole set of the carries, being able to determine whether there exists at least two bits differing between the model packet. The corresponding bit of the packet may not have been corrected or refreshed during the latency period.

According to this embodiment, the addition means comprise an “OR” logic gate whose inputs are connected to the outputs of the first two half-adders and, if n is greater than 3, n−3 “OR” logic gates (ORi) receiving as input the output signal from the “OR” logic gate connected upstream, and the carry of the associated half-adder.

According to another embodiment, if each packet of memory cells comprises n bits, the comparison means can comprise n “EXCLUSIVE OR” logic gates, each gate being able to receive one of the bits of the model packet and the corresponding bit of the packet that has not been corrected or refreshed during the latency period. A multiplexer is controlled by a counter regulated by a clock signal and coupled to the output of the n “EXCLUSIVE OR” logic gates. A half-adder is coupled to the output of the multiplexer, and a first flip-flop is connected to the output of the half-adder, whose output is looped back to the input of the half-adder. A second flip-flop is connected to the half-adder by way of an “OR” logic gate, able to determine whether there exist at least two bits differing between the model packet and the corresponding bit of the packet that has not been corrected or refreshed during the latency period.

The half-adder may be simplified by using a simple “OR” gate to determine the sum instead of an “EXCLUSIVE OR” gate. For example, the memory is organized pagewise, each group of memory cells corresponds to an integer number of pages, and each packet of memory cells corresponds to a word of a page. The device further comprises control means or a controller able to control the refresh means and the retention test means. The device further may comprise a temperature sensor, coupled to the control means, able to detect a variation in temperature.

According to another aspect, there is provided an apparatus possessing a standby mode and an active operating mode, incorporating a device as described above. The test means perform the retention test on all the memory cells in the course of the standby mode. The apparatus can form a component of a wireless communication system. The apparatus can form a cellular mobile telephone.

### BRIEF DESCRIPTION OF THE DRAWINGS

Other advantages and characteristics of the invention may become apparent on examining the detailed description of a mode of implementation and embodiment, which is in no way limiting, and of the appended drawings in which:

FIG. 1 schematically illustrates a random access memory according to the present invention within which the cells are grouped together in rows;

FIG. 2 illustrates in greater detail schematically a memory device according to the invention and more particularly the auxiliary processing means or an auxiliary processor associated with the random access memory according to the present invention;

FIG. 3 represents a schematic flowchart of a mode of implementation of the method according to the present invention;

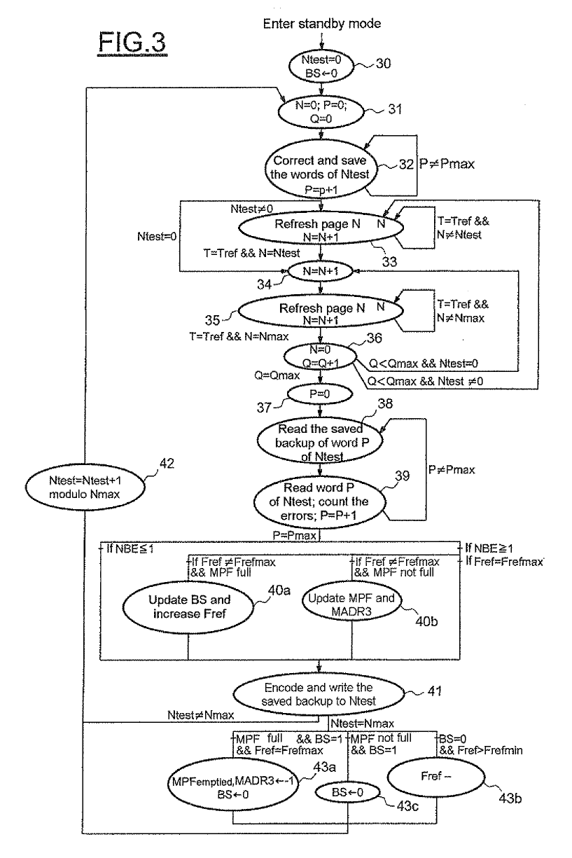

FIGS. 4 to 6 illustrate embodiments of the comparison means or comparer according to the present invention; and

FIG. 7 illustrates an embodiment of means delivering an item of information about the temperature of the memory device or a temperature sensor according to the present invention.

### DETAILED DESCRIPTION OF THE PREFERRED EMBODIMENTS

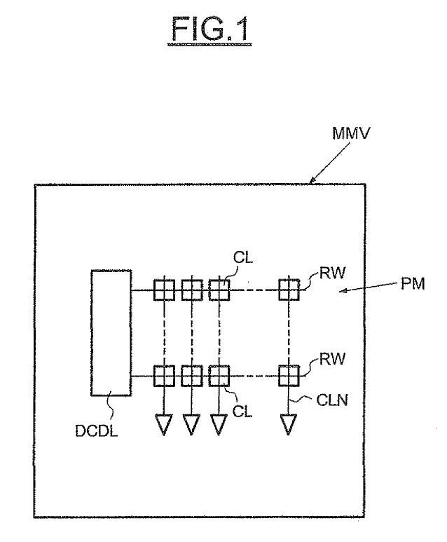

In FIG. 1, the reference MMV designates a dynamic random access memory whose memory plane PM comprises a matrix array of memory cells CL typically organized in rows RW and columns CLN. Each memory cell generally comprises a transistor and a capacitor. Additionally, in a conventional manner known, the memory plane PM is connected to a row decoder DCDL and to a column decoder (which are not represented here for simplifying purposes).

In a general manner, the retention time of all the cells of the memory may be measured continuously and dynamically on the chip (integrated circuit) containing the memory MMV, and the refresh period of this memory may be adjusted accordingly. In the example described herein, the memory is organized into memory pages, a page corresponding to a line of words.

Also, before returning in greater detail to the algorithm for adjusting the refresh period, we may forthwith describe the basic outline of a mode of implementation thereof which comprises in refreshing a selected memory page dubbed the test page less quickly, for example half as quickly as the remaining pages, and observing whether or not this causes errors. The operation is repeated on the entire memory, changing test page each time. The appearance of errors in the content that has not been refreshed for two periods, indicates that the value of the refresh frequency is too low.

More precisely, before refreshing a test page less quickly, a model of the test page is devised. To do this, the content of the test page is saved in a reserved part of the random access memory, for a latency period, and is refreshed at the maximum refresh frequency. In this way, junction leaks are prevented.

In one embodiment, it is possible to save the content of the test page in an external static memory instead of a reserve part of the random access memory. Additionally, this embodiment exploits the presence of an error correction system intended to protect the memory from faults that may arise during the life of the circuit to reduce the refresh frequency of the memory, and consequently its consumption in standby mode; indeed, the only operations performed in standby mode on the memory are these refreshes.

The memory protection system operates in the following manner: each time a data item is written to the memory by the user system, an error correcting code is calculated on the basis of the data item, this data item is supplemented therewith and they are stored together. Each time this data item is read, the consistency between this data item and the correcting code associated with it is checked, and should an error be detected, the latter is corrected.

The number of errors corrected depends on the algorithm of the correcting code used. In the subsequent description, unless indicated otherwise, it may be considered that a single error can be corrected by the correcting code. On completion of the latency period (corresponding for example to two refresh periods if the content of the test page is refreshed half as quickly), the model page is compared with the uncorrected and unrefreshed content of the test page, to which the error correcting code is not applied.

If when all the pages have been tested, no page contains a word exhibiting more than one error (more than k errors, in the general case, with k≦N, N being the number of errors that can be corrected by the error correction system as a function of the error correcting code used) the refresh frequency of the memory is slightly decreased. Otherwise, under the proviso of suitable management of the weakest memory pages as may be seen later, the refresh frequency of the memory is slightly increased.

Thus, the memory self-adjusts its refresh period to what is used. So that the pages of the memory which possess memory cells with a lower retention time than the other memory pages (so-called weak pages), do not penalize the refresh frequency of the whole memory, it is possible to store separately the addresses of the first Vmax weak pages detected, so as to refresh them at the maximum refresh frequency. It may therefore not be taken into account when determining the memory refresh frequency.

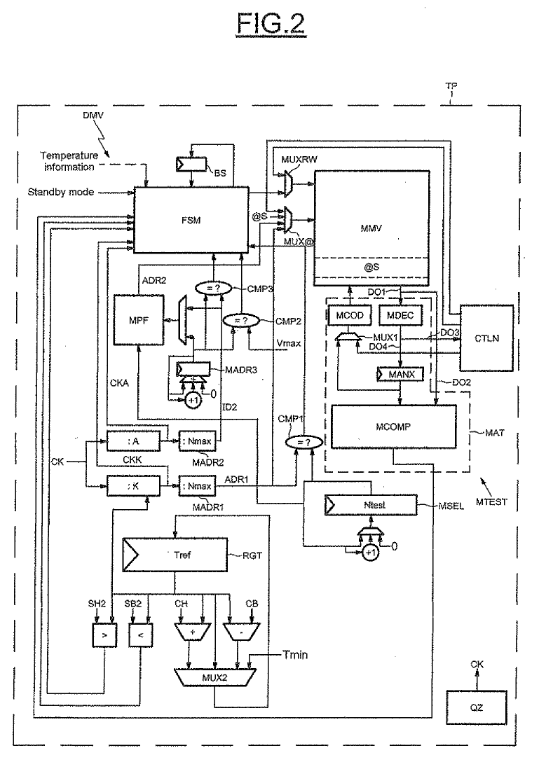

In order to implement the mechanism for regulating the refresh frequency of the random access memory MMV, the memory device DMV comprises (FIG. 2) in addition to the memory MMV, retention test means MTEST, and in particular auxiliary processing means MAT whose structure and functionalities may now be described in greater detail. In a particular embodiment, this device is incorporated into a cellular mobile telephone TP.

The memory device DMV comprises control means FSM, regulated by a signal CKK obtained from a clock signal CK. The latter is for example generated by a quartz oscillator QZ. The signal CK is delivered to a divider by K, with adjustable ratio, so that the frequency of the signal CKK makes it possible to scan the whole set of pages of the memory, i.e. Nmax memory pages.

The value of K is adjusted as a function of the chosen refresh frequency, that is to say with respect to the retention time observed for the memory cells of the memory MMV, as may be seen hereinbelow. The control means FSM therefore send the command to refresh a page of the memory with a period Tret/Nmax, Tret being the retention time observed for the memory cells of the memory MMV.

A counter/divider by Nmax, MADR1, is connected to the output of the divider by K. It outputs an address ADR1 of the memory page of the memory MMV to be refreshed. The address ADR1 is transmitted to the memory MMV by way of a multiplexer MUX@, controlled by the control means ESM like the set of registers and multiplexers of the device DMV that are mentioned subsequently. A command to refresh the memory page at the address ADR1 is sent by the means FSM to the memory MMV via a multiplexer MUXRW.

Additionally, to determine the retention time of the memory cells of the memory, the device DMV comprises means MSEL for selecting pages of the memory to be tested and auxiliary processing means MAT forming test means for performing the retention tests. These means make it possible to adjust the aforesaid value of K. To do this, the selection means MSEL scan the memory MMV in such a way as to successively select each page of the memory. They then deliver an address Ntest of a selected memory pager stated otherwise a test page.

The selection means MSEL are controlled by the control means FSM by way of a multiplexer connected to their input. According to the control of the means FSM, the selection means MSEL may be either reset to zero, or incremented by one unit, or maintained at their present value.

A selected memory page (test page) is not refreshed by the control means ESM. For this purpose, the device DMV comprises an auxiliary comparator CMP1 receiving as input the addresses ADR1 and Ntest. If the two addresses correspond, the control means FSM pass the refreshing of the memory page in question. The test page selected is processed by the auxiliary processing means MAT. The latter comprise decoding means MDEC connected to the output of the random access memory MMV by way of an output bus DO1. The decoding means MDEC form the error correction system.

Furthermore, as already mentioned hereinabove, an error correcting code (ECC) (for example, the Hamming code, as well known to the person skilled in the art) allows the correction of one bit per packet of memory cells. The error correcting code comprises of additional bits added to each word during the writing thereof to the memory. These additional bits are processed by the decoding means or a decoder MDEC when the word is read, so as to detect and correct a possible k errors per word (for example, one error per word).

Thus, the decoding means MDEC make it possible to correct errors of the data of the memory by virtue of the use of the additional bits constituting the error correcting code implemented within the memory device as mentioned hereinabove. In this example it is considered that the model content of the test page is saved in a reserve part of the memory MMV (or temporary memory), with address @S, that the user is not entitled to use. In other embodiments, the safe memory area may be a static memory coupled to the random access memory.

The reserved part of the memory MMV, with address @S, serves to save the model content of the test page, as was described hereinabove. The reserved part with address ES of the memory may, for example, be refreshed at the maximum refresh frequency. The output of the decoding means MDEC is linked to a register MANX by way of a bus DO4. The register MANX is controlled by the control means FSM. The register MANX receives the test page saved word-by-word so as to be able to perform the comparison with the word tested, refreshed at a lower frequency.

In another embodiment, the size of the register MANX can be adapted to be able to receive several words (or the entire test page saved), especially in the case where reading is performed according to the so-called “Burst” mode, that is to say when several words of one and the same page are read in succession. The output of the register MANX is connected to bitwise comparison means or a bitwise comparator MCOMP. The latter also receive in parallel the data delivered directly as output by the memory MMV via the bus DO2.

The bitwise comparison means MCOMP compare the content of the register MANX, that is to say the model memory page, and the data delivered via the bus DO1, that is to say the data that is not corrected and not refreshed of the corresponding memory page. If the comparison means MCOMP detect at most 1 bit having a different value between the model content and the unrefreshed content (k bits in the general case, with k≦N, if the correcting code deployed in the decoding means MDEC can correct N errors), the value is disregarded, since the decoding means MDEC may be able to correct it when the data of the memory page in question are delivered from the memory.

If there is more than one error, the address of the page in question is saved in another memory, termed the weak pages memory. The page in question may then be refreshed at the maximum refresh frequency, while the other memory pages continue to be refreshed at the same refresh frequency. For this purpose, the device DMV comprises a static memory MPF forming the weak pages memory.

The weak pages memory MPF is regulated by a clock signal CKA formulated from the clock signal CK, which is delivered to a divider by A. The value of A is fixed so that the frequency of the signal CKA makes it possible to refresh the memory of the maximum refresh frequency, that is to say for a minimum retention time of the memory cells. A counter/divider by Nmax, MADR2, therefore scans the Nmax addresses of the memory MMV at the maximum refresh frequency, that is to say Nmax/Tretmin, Tretmin being the lowest retention time of the memory cells. It therefore delivers an index ID2 corresponding to a memory page of the memory MMV.

The index ID2 delivered by the counter/divider MADR2 is compared by a comparator CMP3 with the content of a register MADR3 which stores the number of weak pages actually held in the memory MPF. While the index ID2 is less than the number of weak pages held in the memory MPF, the control means FSM instruct, at each period of the signal CKA, the reading of the weak pages memory MPF at the address ADR2 given by the index ID2.

The address ADR2 of the weak page is sent to the memory MMV by way of the multiplexer MUX@, and a command to refresh this page is sent by the means FSM to the memory MMV, via the multiplexer MUXRW. The register MADR3 may be on the decision of the control means FSM initialized to the value “−1”, maintained at its current value, or incremented by one unit. Additionally, the content of this register MADR3 is compared by way of a comparator CMP2 with the size Vmax of the memory MPF (for example, 100), so as to ascertain whether the latter is full.

If the memory MPF is full, and if the comparison means MCOMP detect more than one error on a test pager the refresh frequency is slightly increased and a flip-flop BS looped back to the control means FSM store the increase in the refresh frequency. In other embodiments, it is possible not to increase the refresh frequency directly, but only to store a request to increase the refresh frequency (for example, in the flip-flop BS) and then to increase the refresh frequency only when the entire memory MMV is tested.

To increase the refresh frequency, the control means FSM modify the value of K, on the basis of the current value of the refresh frequency, the corresponding refresh period being stored in a register RGT. To do this, the control means FSM drive a multiplexer MUX2 connected at the output of the register RGT. The output of the multiplexer MUX2 is looped back to the register RGT in such a way as to deliver the new value of the refresh period Tref, as a function of its previous value.

The control means FSM can control the multiplexer MUX2 by initializing the refresh period to its minimum value, Tmin, by incrementing it by a constant CH, by decrementing it by a constant CB or by maintaining it at its current value, all these values being delivered to the input of the multiplexer MUX2.

In other embodiments, instead of incrementing or decrementing the value of the refresh period, it is possible to modify it by applying a multiplicative coefficient to it. These embodiments are given by way of indication. Furthermore, the control means FSM take care to make sure that the refresh period does not leave the range of values permitted by preventing a new increase in this period if the latter is already greater than the threshold SH2, and a new decrease if the period is already below the threshold SB2.

Finally, if the memory MPF is full, if the comparison means MCOMP detect more than one error on a test page, and if the refresh frequency is at its maximum value, no action is performed. On completion of the test of a test page, it is may be necessary to rewrite the data of the test page to the memory. To do this, the output of the register MANX is connected by way of a multiplexer MUX1 to coding means MCOD, intended to encode all the words written to the memory, in normal mode as in standby mode.

Thus, on completion of the data coding, the coding means MCOD rewrite these data to the random access memory MMV, by way of an input bus DI. The refresh and test steps described hereinabove are carried out in standby mode, a signal for entering this mode being delivered to the control means FSM. On entering the standby mode, the value of the refresh frequency is initialized to its maximum value, corresponding to the worst retention case.

As an illustration, for a temperature of 85° C., the retention time is of the order of 32 ms in the worst case. In normal mode, the operation of the memory is managed by a conventional driver CTLN. In this case, the commands and addresses of the memory pages accessed are transmitted to the memory MMV by way of the multiplexers MUXRW and MUX@. Additionally, the data read in normal operating mode are sent to the driver CTLN via a bus D03.

The data written to the memory in normal operating mode is transmitted by way of the multiplexer MUX1, which receives the data on a second input. Additionally, the control means FSM receive as input an item of information about the outside temperature. This item provides information on the variation in the temperature, in particular its increase. If the temperature increases rapidly, the control means may automatically force the refresh temperature to its maximum value.

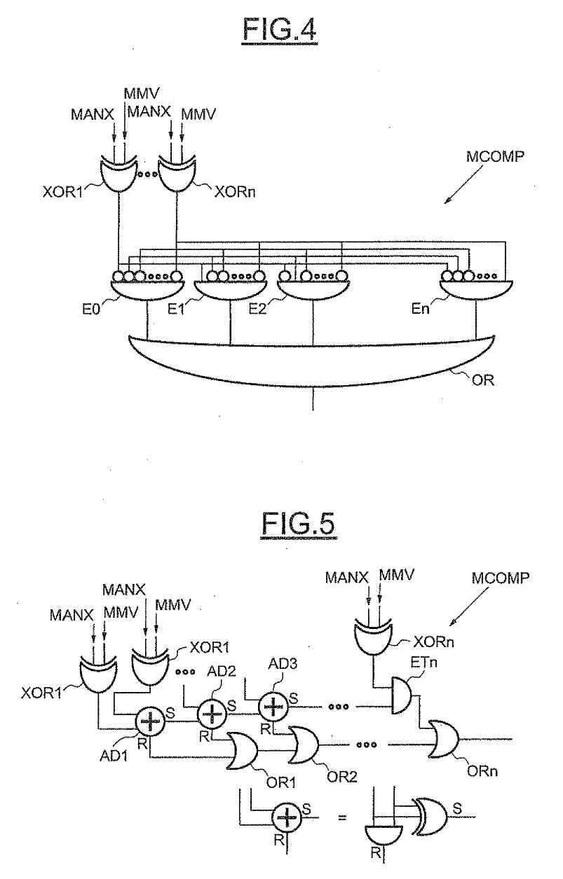

Reference is now made more particularly to FIG. 4, which represents a flowchart describing the various states of the control means FSM which may be embodied in the form of a finite state machine. In this figure, and in this exemplary implementation N denotes the address of memory pages (N≦Nmax), P denotes the address of a word in a page and Q denotes the latency period, that is to say the number of refresh cycles between the writing of the test content in a test page and the reading of the content of this test page with a view to the counting of the errors by the means MCOMP. Q is for example equal to 2.

Additionally, the flowchart of FIG. 4 corresponds, for simplifying reasons, to the case where the number of test pages is equal to 1 (more generally, the test may be performed for several pages simultaneously). Also, Ntest denotes the address of the current test page. Finally, T denotes the current time, counted as a number of cycles, from the last refresh.

On entry to the “standby” mode, the first page of the memory MMV is used as test page, and BS is set to 0 (Ntest=0; BS<-0; step 30). The variables N, P and Q are also initialized to zero (step 31). As indicated above, the refresh period Tref is set to the minimum value (maximum frequency Fref), corresponding to the maximum temperature of use of the system.

At the commencement of the test period, an error, if any, is corrected for each word of the test page and the whole set of corrected words of Ntest is saved in the safe memory area (correction and saving of the words of N test; step 32). As Ntest is equal to zero we go directly to a step 34 where N is incremented by one unit (N=N+1; step 34), then in the course of a step 35, all the other pages of the random access memory are refreshed successively, that is to say as long as N is different from Nmax, and at the refresh period Tref (refresh page N, N=N+1; step 35).

Then, when N is equal to Nmax, in the course of a step 36, N is reinitialized to 0 and the variable Q is incremented by one unit. If Q is less than its maximum value, as Ntest is equal to zero, steps 34 to 36 are repeated as long as Q is different from Qmax. When Q reaches its maximum value Qmax, the variable P is initialized in the course of a step 37. Then, in the course of a step 38, the first word of the model test page is read (reading of the saved backup of the word P of Ntest; step 38).

The content of the same uncorrected and unrefreshed word P of Ntest is then read and is compared with the model content of the word. On completion of the comparison, a flag is set to indicate whether there is more than one error, which may therefore not be able to be corrected by the error correcting code. P is incremented by one unit (read word P of Ntest, count the errors; P=P+1; step 39). Then, as long as P is different from Pmax, steps 38 and 39 are repeated.

When P reaches its maximum value, if no word of the page comprises more than one error, no action is carried out since the correcting code is capable of correcting one error, if any, per word. If at least one word of the page comprises more than one error, if the weak pages memory is not full and if the refresh frequency is not at its maximum value, the address of the page tested and stored in the weak pages memory MPF and the register MADR3 is updated (step 40b; update MPF is MADR3).

If at least one word of the page comprises more than one error and if the weak pages memory is full, the refresh frequency is increased and the flip-flop BS stores this increase (step 40a, update BS and increase Fref). Next, in the course of a step 41, the model content saved in the safe memory area is coded and it is rewritten to the memory MMV of the address Ntest (encoding and writing of the model content into Ntest; step 41).

As Ntest is different from Nmax, the value of Ntest is incremented by one unit (Ntest=Ntest+1, model Nmax; step 42). Next, steps 31 and 32 are repeated. On completion of step 32, as Ntest is different from zero, we go to step 33 where the memory page is refreshed at the address N and N is incremented by one unit (refresh page N, N=N+1; step 33). As long as N is different from Ntest and at the refresh period Tref, step 33 is repeated.

If N is equal to Ntest, the value of N is incremented directly by one unit in the course of step 34 without refreshing the test page considered. Next, we go to a step 35 where page N is refreshed again and the value of N is incremented by one unit (refresh page N, N=N+1; step 35). Step 35 is repeated with a refresh period Tref and as long as N is different from Nmax.

On completion of step 35, steps 36 to 41 are repeated as described above. When Ntest is equal to Nmax on completion of step 41, all the pages have been tested. The weak pages memory MPF and the addressing means MADR3 are then updated in the following manner.

If BS=“1”, indicating that the refresh frequency has already had to be increased in the course of the test cycle, and that the refresh frequency is at its maximum value: the weak pages memory MPF is full, it is then emptied; to do this the register MADR3 is reset to its initial value, −1, (step 43a, NPF emptied, MADR3<-“−1”, BS<-“0”), (indeed, if the standby mode is entered while the temperature is very high, there is a risk of there being too many pages for which it may not be possible to lower the refresh frequency; the addresses of pages stored in MPF may not necessarily correspond to those of the weakest pages. It is then better to recommence the test up to a time that the temperature has dropped sufficiently for it to be possible to operate with an ideally filled weak pages memory).

If the flip-flop BS indicates that the refresh frequency has not been increased (BS=“0”), during the test of the memory and that the latter is greater than its minimum value, (Fref>Frefmin), this frequency is reduced slightly (step 43b, Fref--). In the other cases, BS is reset to 0 (step 43c; BS<-0) and no other action is performed. Next, it is again the first page of the memory which becomes the test page (Ntest=Ntest+1 model Nmax, step 42) and the operations described previously are performed again successively for all the pages of the memory so as to carry out a new cycle of regulation of the refresh period.

We now refer to FIGS. 4 to 6, which represent embodiments of the comparison means MCOMP, to test a word. FIG. 4 illustrates a so-called “parallel” embodiment. In this case, the comparison means MCOMP comprise n+1 “AND” logic gates, E0, E1, E2 . . . En, n corresponding to the number of bits per word.

The logic gate E0 comprises n inverting inputs. Each logic gate Ek comprises n−1 inverting inputs, the k^{th} input being non-inverting, k varying from 1 to n. Each input of the logic gate Ek is connected to the output of an “EXCLUSIVE OR” logic gate, respectively XOR1, . . . XORn.

Each of these “EXCLUSIVE OR” logic gates receives for a tested word, a bit of this word arising from the register MANX and a bit of this word arising directly from the memory MMV after the latency period. If there is a difference between these two bits, the logic gate XOR1 delivers the value “1”, and “0” otherwise. The first gate E0 makes it possible to flag whether there is no error. The second gate E1 flags whether there is an error in the first bit, and the gate Ek flags whether there is an error in the k^{th} bit.

The whole set of outputs of the gates E0, . . . En are connected to an “OR” logic gate referenced OR which indicates the presence of a multiple error if the value that it delivers is equal to “0” It is possible to connect an inverter to the output of the “OR” gate, so that it delivers a signal indicating the presence of at least two errors.

FIG. 5 illustrates another embodiment of the comparison means MCOMP also of parallel type. In this embodiment, the means MCOMP comprise n−2 half-adders AD1, AD2, AD3, . . . , ADn−2 connected in series, and an “AND” logic gate, referenced ETn, which represents a simplified form of a half-adder. The first half-adder AD1 receives the output of the two “EXCLUSIVE OR” logic gates, XOR1 and XOR2 described previously.

Next, each following half-adder ADi, i varying from 2 to n−2, receives as input on the one hand the output signal from the following “EXCLUSIVE OR” gate, referenced XORi+1, and on the other hand, the output S from the half-adder ADi−1 connected upstream. The “AND” logic gate, ETn, receives the output signal from the logic gate XORn, and the output signal from the half-adder ADn−2.

Furthermore, each half-adder ADi delivers a carry R. The comparison means MCOMP also comprise n−2 “logic OR” gates able to receive the carry R of a half-adder and the output of the previous OR logic gate. The first “OR” logic gate receives the carries of the first two half-adders. The last “OR” logic gate, ORn receives as input the signal delivered by the previous “OR” logic gate ORn−1 and the output of the gate ETn.

Of course, it is possible to replace the n “OR” logic gates by a single “OR” logic gate with n−1 inputs, all receiving the outputs R of the half-adders as well as the output of the gate ETn. The carries are added together successively with the aid of “OR” logic gates OR1, . . . , ORn, and if any one of the carries R switches to “1”, the output of the “OR” gate concerned switches to “1”, this signifying that there are at least two errors.

Conventionally, a half-adder may be embodied with the aid of an “EXCLUSIVE OR” logic gate (as represented in FIG. 5) for the output sum S and an “AND” logic gate for the carrier R. However, the “EXCLUSIVE OR” gate for the sum S may be replaced in this case of use by a simple “OR” logic gate.

FIG. 6 represents a so-called “serial” embodiment of the comparison means MCOMP. A multiplexer MUX4 controlled by a counter CPT which is regulated by the clock signal CK. The multiplexer MUX4 receives the outputs of the logic gates XOR1, . . . XORn. The counter CPT regulates the multiplexer MUX4 in such a way as to select the various inputs successively. Each input bit is then delivered to a half-adder ADD coupled to a flip-flop BSS.

In this example, the half-adder ADD comprises an “AND” logic gate, ETADD, and an “OR” logic gate, ORADD, that are coupled in parallel. The gates ETADD and ORADD receive as input the output of the multiplexer MUX4 and the output of the flip-flop BSS. The output of the logic gate ORADD is connected to the input of the flip-flop BSS. The output of the logic gate ETADD is connected to another flip-flop BSR, via an “OR” logic gate, ORSUP, which also receives as input the output of the flip-flop BSR.

If the bit delivered as input is equal to “1” or if the previous result stored by the flip-flop BSS is already “1” the flip-flop BSS is set to “1”, indicating the presence of at least one bit equal to “1”. If the bit delivered as output from the multiplexer MUX4 is equal to “1” and if the flip-flop BSS is already “1”, the flip-flop BSR is set to “1”. If the flip-flop BSR was already “1”, it retains this result, this indicating the presence of at least two errors.

The flip-flops BSS and BSR are regulated by the clock signal CK and can be reset to zero by a reset to zero signal RZ. The embodiments of the comparison means described hereinabove are suitable for the case where the error correcting code corrects just a single error. The person skilled in the art may be able to adapt the comparison means in the case where the error correcting code corrects k errors.

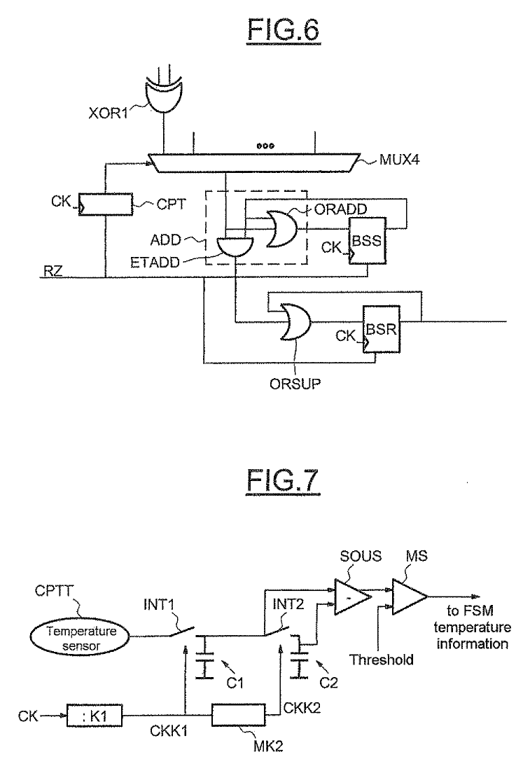

FIG. 7 represents an exemplary embodiment of the means for detecting the variation in temperature. These means comprise a temperature sensor CPTT as well as two sampling means, each being formed of a switch respectively INT1, INT2 associated with a capacitor C1 and C2 respectively. The switches may for example be embodied by means of transistors.

The switches INT1 and INT2 are controlled by two clock signals CKK1 and CKK2, in phase opposition and non-overlapping. The signal CKK1 arises from the clock signal CK respectively divided by an integer K1 and the signal CKK2 is obtained from the signal CKK1 by way of the means MK2 suitable for devising and delivering the signal CKK2 in phase opposition with respect to CKK1 and non-overlapping.

A subtractor SOUS compares the difference between the two values sampled by the capacitors C1 and C2. Next, thresholding means MS compare this difference with a predefined threshold. This temperature information is delivered to the control means FSM which decide or otherwise to force an increase in the refresh frequency if the variation is greater than the chosen threshold.

1-38. (canceled)

39. A method for refreshing a dynamic random access memory coupled to an error correction system which uses an error correcting coder the dynamic random access memory comprising groups of memory cells storing bits, each group of memory cells being subdivided into packets of memory cells, each packet of memory cells being supplemented with the error correcting code, the method comprising:
performing a retention test on each group of memory cells comprising
saving a group of memory cells under test in a safe memory area, after correction of errors therein by the error correction system, to provide a model group of memory cells comprising model packets of memory cells,
after a latency period, comparing bitwise between the model group of memory cells and a test group of memory cells that has not been corrected or refreshed during the latency period,
detecting erroneous bits in each packet of the test group of memory cells having values differing from bits of the respective model packet of the model group of memory cells, and
determining a packet of the test group of memory cells to be erroneous when it comprises a number of erroneous bits greater than a limit value being less than or equal to a number of bits capable of being corrected by the error correction system; and
increasing a memory refresh frequency if a number of test groups of memory cells comprising at least one erroneous packet is greater than a threshold.

40. The method according to claim 39 wherein the error correction system is capable of correcting one bit per packet of memory cells.

41. The method according to claim 39 wherein the latency period comprises N refresh periods.

42. The method according to claim 39 wherein on completion of detecting erroneous bits, the content of the model group of memory cells is supplemented with an error correcting code, the content being saved within the dynamic random access memory in place of the corresponding group of memory cells.

43. The method according to claim 39 wherein the number of groups of memory cells comprising at least one erroneous packet comprise weak memory cells; and wherein when a number of weak memory cells is less than or equal to the threshold, then an address of the group of weak memory cells is stored so as to refresh them at a maximum memory refresh frequency.

44. The method according to claim 39 wherein increasing a memory refresh frequency is performed if the memory refresh frequency has not reached a maximum memory refresh frequency.

45. The method according to claim 39 wherein when all the groups of memory cells of the dynamic random access memory have been tested, the value of the memory refresh frequency is decreased if it has not been increased in the course of the test.

46. The method according to claim 39 wherein the number of groups of memory cells comprising at least one erroneous packet comprise weak memory cells: and wherein when all the groups of memory cells of the dynamic random access memory have been tested, if a number of weak memory cells having is greater than or equal to the threshold and if the memory refresh frequency comprises a maximum memory refresh frequency, then the weak memory cells are considered to be zero.

47. The method according to claim 39 wherein each group of memory cells forming a group of test memory cells is selected successively so as to perform the retention test.

48. The method according to claim 47 wherein the memory cells of the dynamic random access memory are refreshed cyclically, with exception to the group of test memory cells, in parallel with the retention test.

49. The method according to claim 39 wherein the dynamic random access memory is organized pagewise; and wherein each group of memory cells corresponds to an integer number of pages, and each packet of memory cells corresponds to a word of a page.

50. The method according to claim 39 wherein an increase in the memory refresh frequency is imposed if a variation in a temperature within the dynamic random access memory exceeds a temperature threshold.

51. The method according to claim 39 wherein the dynamic random access memory is incorporated into an apparatus having a standby mode and an active operating mode; and wherein the retention test is performed on the memory cells at least during the standby mode.

52. The method according to claim 51 wherein the apparatus is a component of a wireless communication system.

53. The method according to claim 52 wherein the wireless communication system comprises a cellular mobile telephone.

54. A device for refreshing a dynamic random access memory comprising groups of memory cells storing bits, each group of memory cells being subdivided into packets of memory cells, the dynamic random access memory being coupled to an error correction system and having an error correcting code for correcting a number of erroneous bits per packet of memory cells associated with each group of memory cells, the device comprising:
a retention testing module for performing a retention test on each group of memory cells and comprising
a safe memory area for saving a group of memory cells under test after a correction of errors therein by the error correction system, the saved group of memory cells providing a model group of memory cells comprising model packets of memory cells, and
a first comparer
for performing, after a latency period, a bitwise comparison between the model group of memory cells and a test group of memory cells having packets of memory cells that has not been corrected or refreshed during the latency period,
for detecting in each packet of memory cells in each test group of memory cells erroneous bits having values different from bits of a corresponding model packet of the model group of memory cells, and
determining the packet of memory cells to be erroneous if the test packet of memory cells comprises a number of erroneous bits greater than a limit value being less than or equal to a number of bits that can be corrected by the error correcting system; and
a first refresh controller for increasing a memory refresh frequency when a number of test groups of memory cells comprising at least one erroneous packet is greater than a threshold.

55. The device according to claim 54 wherein said safe memory area comprises a reserved area of the dynamic random access memory and is refreshed at a maximum memory refresh frequency, for saving the model group of memory cells.

56. The device according to claim 54 wherein said safe memory area comprises a static memory coupled to the dynamic random access memory for saving the model group of memory cells.

57. The device according to claim 54 further comprising a supplementing device coupled to the dynamic random access memory for supplementing the content of the model group of memory cells with the error correcting code and for saving a coded content of the model group of memory cells in the dynamic random access memory in place of the test group of memory cells.

58. The device according to claim 54 further comprising a memory for weak pages for saving addresses of the groups of memory cells being weak memory cells and comprising at least one erroneous packet.

59. The device according to claim 58 wherein the weak memory cells are refreshed at a maximum memory refresh value.

60. The device according to claim 58 further comprising a second comparer for comparing a number of the weak memory cells and the threshold.

61. The device according to claim 54 furthermore comprising a recorder for effecting of an increase in the memory refresh frequency.

62. The device according to claim 61 further comprising a second refresh controller being coupled to said recorder and reducing the memory refresh frequency.

63. The device according to claim 58 further comprising a driver for updating and reinitializing the memory for weak pages.

64. The device according to claim 54 wherein said retention testing module comprises a selector for successively selecting groups of memory cells and scanning the selected groups of memory cells, the selected groups of memory cells forming groups of test cells.

65. The device according to claim 54 further comprising a refreshing module for cyclically refreshing the groups of memory cells.

66. The device according to claim 65 further comprising a third comparer being coupled between said refreshing module and said retention testing module for comparing addresses of the group of memory cells being refreshed by said refreshing module, and the group of memory cells under test, thereby said refreshing module does not refresh the group of memory cells under test.

67. The device according to claim 54 wherein the error correction system is able to correct one error per packet of memory cells.

68. The device according to claim 54 wherein each packet of memory cells comprises n bits; wherein said first comparer, for each packet of memory cells, comprises:
n EXCLUSIVE OR logic gates, each gate being able to receive one of the bits of the model packet of memory cells and the corresponding bit of the packet that has not been corrected or refreshed during the latency period;
n AND logic gates with n−1 inverting inputs; and
an AND logic gate with n inverting inputs;
the set of AND logic gates being connected in parallel, to the output of the n EXCLUSIVE OR logic gates, and an OR logic gate connected to the output of the set of AND logic gates, for detecting at least two bits differing between the model packet of memory cells and the corresponding bit of the packet that has not been corrected or refreshed during the latency period.

69. The device according to claim 54 wherein each packet of memory cells comprises n bits; wherein said first comparer comprises:
n EXCLUSIVE OR logic gates, each gate being able to receive one of the bits of the model packet of memory cells and the corresponding bit of the packet that has not been corrected or refreshed during the latency period; and
n−1 half-adders connected in series and at the output of the EXCLUSIVE OR logic gates to receive, for the first half-adder, the output signals of the first two EXCLUSIVE OR gates, and for the other adders, on the one hand a sum delivered by the half-adder connected upstream, and on the other hand an output signal from an EXCLUSIVE OR logic gate, each half-adder being able to deliver a carry signal, said first comparer comprises an adder for adding the whole set of the carries, able to determine whether there exist at least two bits differing between the model packet and the corresponding bit of the packet that has not been corrected or refreshed during the latency period.

70. The device according to claim 69 further comprising an adder having an OR logic gate being connected to the outputs of the first two half-adders; and wherein if n is F greater than 3, n−3 OR logic gates receive as input the output signal from the OR logic gate connected upstream and the carry of the associated half-adder.

71. The device according to claim 54 wherein each packet of memory cells comprises n bits; and wherein said first comparer comprises:
n EXCLUSIVE OR logic gates, each gate being able to receive one of the bits of the model packet and the corresponding bit of the packet that has not been corrected or refreshed during the latency period;
a counter;
a multiplexer controlled by said counter regulated by a clock signal and coupled to an output of the n EXCLUSIVE OR logic gates;
a half-adder coupled to an output of said multiplexer;
a first flip-flop connected to an output of said half-adder and having an output being looped back to the input of said half-adder; and
a second flip-flop being connected to said half-adder by way of an OR logic gate for detecting at least two bits differing between the model packet of memory cells and the corresponding bit of the packet that has not been corrected or refreshed during the latency period.

72. The device according to claim 54 wherein the dynamic random access memory is organized pagewise; and wherein each group of memory cells corresponds to an integer number of pages, and each packet of memory cells corresponds to a word of a page.

73. The device according to claim 65 further comprising a controller for managing said refreshing module and said retention testing module.

74. The device according to claim 73 further comprising a temperature sensor coupled to said controller and detecting a variation in temperature.

75. An electronic device having a standby mode and an active operating mode, the electronic device comprising:
a retention testing module for performing a retention test on each group of memory cells during at least the standby mode and comprising
a safe memory area for saving a group of memory cells under test after a correction of errors therein by the error correction system, the saved group of memory cells providing a model group of memory cells comprising model packets of memory cells, and
a first comparer
for performing, after a latency period, a bitwise comparison between the model group of memory cells and a test group of memory cells having packets of memory cells and not being corrected or refreshed during the latency period,
for detecting in each packet of memory cells in each test group of memory cells erroneous bits having values different from bits of a corresponding model packet of the model group of memory cells, and
determining the packet of memory cells to be erroneous if the packet of memory cells comprises a number of erroneous bits greater than a limit value being less than or equal to a number of bits that can be corrected by the error correcting system; and
a first refresh controller for increasing a memory refresh frequency when a number of test groups of memory cells comprising at least one erroneous packet is greater than a threshold.

76. The electronic device according to claim 75 wherein the electronic device comprises a wireless communication device.

77. The electronic device according to claim 75 wherein the electronic device comprises a cellular mobile telephone.
